(19) United States
(12) Patent Application Publication
(10) Pub. No.: US 2002/0145582 A1
(43) Pub. Date: Oct. 10, 2002

(54) Display device and manufacturing method thereof

(76) Inventors: Shunpei Yamazaki, Tokyo (JP); Eiichiro Tsuji, Kanagawa (JP)

Correspondence Address: NIXON PEABODY, LLP, 8180 GREENSBORO DRIVE, SUITE 800, MCLEAN, VA, 22102, US

(21) Appl. No.: 09/985,463

(22) Filed: Nov. 2, 2001

(30) Foreign Application Priority Data
Aug. 31, 2000 (JP) 2000-261983

(51) Int. Cl. G09G 3/36; H01L 21/00

(52) U.S. Cl. 345/92; 438/30; 438/34

(57) ABSTRACT

This invention is intended to reduce the manufacturing cost of an active matrix type display device and to provide an inexpensive display device. To reduce the manufacturing cost of the active matrix type display device, TFT's used for a pixel sections are all TFT's of one conductive type (indicating p channel type TFT's or n channel type TFT's), and a driving circuit is formed out of the TFT's of the same conductive type as that of the pixel section. It is thereby possible to reduce manufacturing steps and to reduce the manufacturing cost.

### BACKGROUND OF THE INVENTION

1. Field of the Invention

The present invention relates to a display device which includes a pixel section and a driving circuit for transmitting a signal to the pixel section both of which sections are provided on the same insulator. More specifically, the present invention relates to a liquid crystal display device having a liquid crystal material held between electrodes or a self-luminous display device having a luminous material between electrodes. In addition, the present invention relates to a device (to be referred to as “luminous device” hereinafter) which includes an element (to be referred to as “luminous element” hereinafter) having a luminous material held between electrodes. The present invention can also be applied to a device (to be referred to as “liquid crystal display device” hereinafter) which includes an element (to be referred to as “liquid crystal element” hereinafter) having a liquid crystal material held between electrodes. It is noted that the liquid crystal display device and the self-luminous display device will be generally referred to as display devices in the present specification.

2. Description of the Related Art

Recently, the development of an active matrix type display device which has a pixel section formed out of a thin film transistor (to be referred to as “TFT” hereinafter) has been underway. A liquid crystal display device is typical of the active matrix type display device. On the liquid crystal display device, a TFT serving as a switching element which controls voltage applied to a liquid crystal layer is provided on each pixel. In addition, a self-luminous display device which uses an EL (electro Luminescence) material has a TFT provided on each pixel provided in a pixel section, the quantity of current carried to an EL element is controlled by the TFT to thereby control the luminous brightness of each pixel. The active matrix type display device stated above is characterized by being capable of uniformly supplying current to respective pixels even if the number of pixels increases and being suited to obtain a highly accurate image.

In addition, the active matrix type display device is advantageous in that circuits such as a shift register, a latch and a buffer, as driving circuits for transmitting a signal to the pixel section can be formed out of TFT's on the same insulator. This makes it possible to realize a display device having a very small number of contacts with an external circuit and capable of displaying a highly accurate image.

The equivalent circuit for the pixel of the active matrix type self-luminous display device is shown in FIG. 10A. In FIG. 10A, reference symbol 1001 denotes a source wiring, 1002 denotes a gate wiring, 1003 denotes a TFT which functions as a switching element (to be referred to as “switching TFT” hereinafter), and 1004 denotes a capacitor which is electrically connected to the drain of the switching TFT 1003.

In addition, the gate electrode of a current-control TFT 1005 is electrically connected to the drain of the switching TFT 1003. The source of the current-control TFT 1005 is electrically connected to a current supply line 1006 and the drain thereof is electrically connected to an EL element 1007. That is, the current-control TFT 1005 functions as an element which controls current flowing in the EL element 1007.

As can be seen, two TFT's are provided in one pixel and these two TFT's have different functions to allow controlling the luminescent brightness of the EL element. As a result, light emission is carried out almost for one frame period. Even if a highly accurate pixel section is provided, an image can be displayed while keeping the luminescent brightness suppressed. The active matrix type display device is further advantageous in that a shift register and a sampling circuit serving as driving circuits each of which transmits a signal to the pixel section and each of which are made of TFT's can be formed on the same substrate. This makes it possible to manufacture quite a compact self-luminous display device.

FIG. 10B is an equivalent circuit diagram for the pixel of a liquid crystal display device. In FIG. 10B, a source wiring 1011, a gate wiring 1012, a switching TFT 1013, a retention capacitance 1015, a capacitance line 1014 and a liquid crystal layer 1016 are provided.

A typical liquid crystal display device has one TFT or a multi-gate structure TFT provided in one pixel. Since liquid crystals are driven with an alternating current, a method referred to as a frame inversion driving method is often employed. Since the TFT functions as a switching element and holds voltage applied to a liquid crystal layer, low leak current is required of the TFT. Charges transferred from a source wiring to the pixel while the TFT is turned on are retained for a field period. The resistance of the liquid crystals should be high. Characteristics required of the TFT include sufficiently high ON-state current to allow charging a pixel capacitance (liquid crystals themselves) in a scan period, sufficiently low OFF-state current to allow retaining charges in a field period, sufficiently low parasitic capacitance between a gate and a drain and the like. If the pixel capacitance is low, capacitance retention operation is insufficient. The retention capacitance is provided to compensate for the pixel capacitance and to avoid the influence of the parasitic capacitance.

On the other hand, since high driving voltage is applied to the buffer circuit serving as the driving circuit, it is necessary to increase the withstand voltage of the buffer circuit so that the buffer circuit is not broken even if high voltage is applied thereto. In addition, it is necessary to secure a sufficient ON-state current value (which is drain current carried to the TFT during the ON-state operation of the TFT) so as to improve current driving capability.

### PROBLEM TO BE SOLVED BY THE INVENTION

Nevertheless, the active matrix type display device is disadvantageous in that if the manufacturing steps of the TFT are complicated, manufacturing cost thereof is pushed up. Further, a plurality of TFT's are simultaneously manufactured. Due to this, if the manufacturing steps are complicated, it is disadvantageously difficult to ensure high yield. If an operating defect occurs to the driving circuit, in particular, a linear defect that a pixel column cannot operate, sometimes occurs.

It is an object of the present invention to provide an inexpensive active matrix type display device capable of reducing the manufacturing cost of the display device. It is another object of the present invention to provide an inexpensive electronic equipment which employs a display device of the present invention as a display section.

### SUMMARY OF THE INVENTION

The present invention is characterized in that to reduce the manufacturing cost of an active matrix type display device, TFT's used for a pixel sections are all TFT's of one conductive type (indicating p channel type TFT's or n channel type TFT's), and in that a driving circuit is formed out of the TFT's of the same conductive type as that of the pixel section. It is thereby possible to greatly reduce the number of manufacturing steps and to reduce the manufacturing cost.

The particularly important respect of the invention is in that the driving circuit is formed only out of TFT's of one conductive type. That is, while an ordinary driving circuit is designed based on a CMOS circuit in which an n channel type TFT and a p channel type TFT are complementarily combined, the driving circuit according to the present invention is formed only by combining p channel type TFT's or n channel type TFT's.

By providing such a configuration, it is possible to reduce the number of masks used to dope impurities controlling the conductivity type in a TFT manufacturing step. As a result, it is possible to shorten manufacturing steps and to reduce the manufacturing cost.

As stated above, the configuration of the present invention is a display device having a pixel section and a driving circuit formed on the same insulator, characterized in that all TFT's for the pixel section and the driving circuit are p channel type TFT's; and that each p channel type TFT of the pixel section has an offset gate structure.

In addition, another invention is a display device having a pixel section and a driving circuit formed on the same insulator, characterized in that all TFT's for the pixel section and the driving circuit are p channel type TFT's; each p channel TFT of the pixel section has an LDD region outside of a gate electrode; and that each p channel TFT of the driving circuit has an LDD region overlapped with the gate electrode.

Further, yet another invention is a display device having a pixel section and a driving circuit formed on the same insulator, characterized in that all TFT's for the pixel section and the driving section are p channel type TFT's; and that a source wiring and a gate electrode of the pixel section are formed on a first insulating film, and a gate wiring connected to the gate electrode crosses the source wiring through a second insulating film.

The display device is characterized in that said driving circuit includes an EEMOS circuit or an EDMOS circuit or that said driving circuit includes a decoder consisting of a plurality of NAND circuits.

Moreover, a display device manufacturing method according to the present invention is characterized by including: a first step of forming a first semiconductor film for forming a TFT of a driving circuit on an insulator, and a second semiconductor film for forming the TFT of a pixel section on the insulator; a second step of forming a gate electrode consisting of a first conductive film and a second conductive film inside of the first conductive film, on each of an upper layer of the first semiconductor film and an upper layer of the second semiconductor film; a third step of forming a first p type semiconductor region overlapped with the first conductive film, on each of the first semiconductor film and the second semiconductor film; a fourth step of forming a second p type semiconductor region not overlapped with the first conductive film, on each of the first semiconductor film and the second semiconductor film; and that a fifth step of removing a section in which the first conductive film is overlapped with the first p type semiconductor region by etching.

In addition, another example of the display device manufacturing method according to the present invention is characterized by including: a first step of forming a first semiconductor film for forming a TFT of a driving circuit on an insulator, and a second semiconductor film for forming the TFT of a pixel section on the insulator; a second step of forming a gate electrode consisting of a first conductive film and a second conductive film inside of the first conductive film, on each of an upper layer of the first semiconductor film and an upper layer of the second semiconductor film; a third step of forming a first p type semiconductor region overlapped with the first conductive film, on each of the first semiconductor film and the second semiconductor film; a fourth step of forming a second p type semiconductor region not overlapped with the first conductive film, on each of the first semiconductor film and the second semiconductor film; and a fifth step of removing a section in which the first conductive film on the second semiconductor film is overlapped with the first p type semiconductor region by etching, and forming an offset region.

Additionally, yet another example of the display device manufacturing method according to the present invention is characterized by including: a first step of forming a first semiconductor film for forming a TFT of a driving circuit on an insulator, and a second semiconductor film for forming the TFT of a pixel section on the insulator; a second step of forming a first insulating film on the first semiconductor film and the second semiconductor film; a third step of forming a gate electrode consisting of a first conductive film and a second conductive film inside of the first conductive film, and a source wiring, on the first insulating film to correspond to each of the first semiconductor film and the second semiconductor film; a fourth step of forming a first p type semiconductor region overlapped with the first conductive film, on each of the first semiconductor film and the second semiconductor film; a fifth step of forming a second p type semiconductor region not overlapped with the first conductive film, on each of the first semiconductor film and the second semiconductor film; a sixth step of removing a section in which the first conductive film is overlapped with the first p type semiconductor region by etching; a seventh step of forming a second insulating film on the gate electrode and the source wiring; and that an eighth step of forming a gate wiring on the second insulating film.

As stated so far, according to the present invention, the reflection type display device can be realized by using four photomasks and the manufacturing cost of the active matrix type display device can be reduced.

### BRIEF DESCRIPTION OF THE DRAWINGS

FIG. 1 is a view showing a gate side driving circuit;

FIG. 2 is a timing chart for decoder input signals;

FIG. 3 is a view showing a source side driving circuit;

FIG. 4 is a view showing the configurations of an EEMOS circuit and an EDMOS circuit;

FIG. 5 is a view showing a shift register;

FIG. 6 is a cross-sectional view for explaining the structure of the pixel section of a self-luminous device formed out of PTFT's;

FIG. 7 is a top view for explaining the structure of the pixel section of the self-luminous device formed out of PTFT'S;

FIG. 8 is a cross-sectional view for explaining the structure of the pixel section of the self-luminous device formed out of PTFT's;

FIG. 9 is a cross-sectional view for explaining the manufacturing steps of an E type PTFT and a D type PTFT;

FIG. 10 is an equivalent circuit diagram for the pixel section;

FIG. 11 is a cross-sectional view for explaining the structure of the pixel section of a liquid crystal display device formed out of PTFT's;

FIG. 12 is a top view for explaining the structure of the pixel section of the liquid crystal display device formed out of PTFT's;

FIG. 13 is a cross-sectional view for explaining the structure of the pixel section of the liquid crystal display device formed out of PTFT's;

FIG. 14 is a view for explaining the detail of an offset gate structure;

FIG. 15 is a cross-sectional view for explaining the structure of the pixel section of a liquid crystal display device formed out of PTFT's;

FIG. 16 is a cross-sectional view for explaining the structure of the pixel section of a transmission type liquid crystal display device formed out of PTFT's;

FIG. 17 is a cross-sectional view for explaining the structure of the transmission type liquid crystal display device formed out of PTFT's;

FIG. 18 is an assembly drawing of the main constituent elements of the liquid crystal display device;

FIG. 19 is a view for explaining the structure of a terminal section;

FIG. 20 is a block diagram for explaining the configuration of an electronic equipment;

FIG. 21 is a view for explaining a method of manufacturing a crystalline semiconductor film;

FIG. 22 is a view for explaining one example of the electronic equipment;

FIG. 23 is a view for explaining one example of the electronic equipment; and

FIG. 24 is a graph showing the gate voltage (VG)-to-drain current (ID) characteristic of a PTFT.

### DETAILED DESCRIPTION OF THE INVENTION

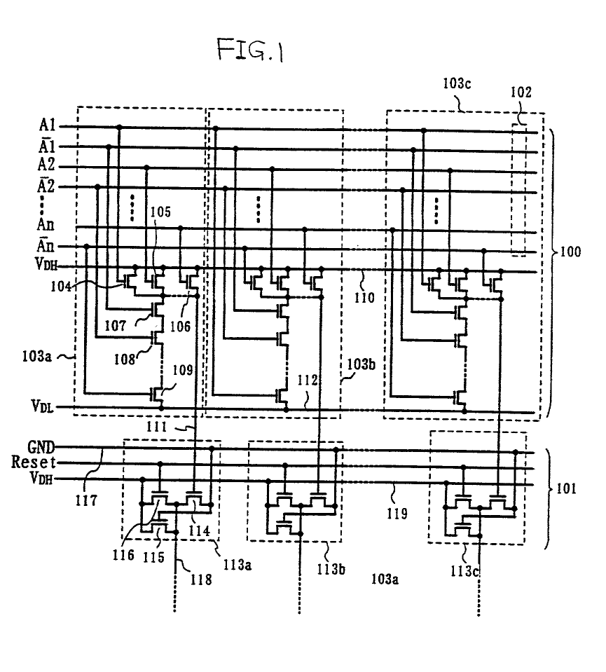

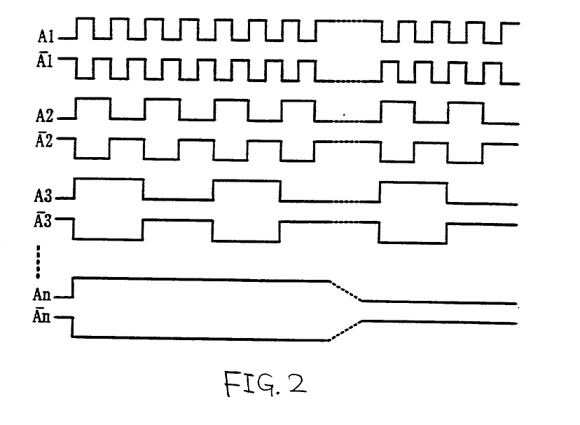

A driving circuit used in the present invention will be described hereinafter with reference to FIGS. 1 and 2. FIG. 1 shows one example of a gate side driving circuit. In the present invention, a decoder which uses p channel type TFT's shown in FIG. 1 is provided in place of an ordinary shift register.

In FIG. 1, reference symbol 100 denotes the decoder of the gate side driving circuit and 101 denotes the buffer section thereof. It is noted that the buffer section means a section in which a plurality of buffers (buffer amplifiers) are integrated. In addition, a buffer means a circuit which conducts driving without the influence of a buffer in a rear stage on a buffer in a front stage.

In the gate side decoder 100, reference symbol 102 denotes the input signal line (to be referred to as “select line” hereinafter) of the decoder 100. Herein, the select lines A1 and /A1 (for signal reversed in polarity from A1), A2 and /A2 (for signal reversed in polarity from A2), . . . An and /An (for signal reversed in polarity from An) are shown. Namely, it suffices to assume that 2n select lines are aligned.

The number of select lines is determined according to the number of gate wirings outputted from the gate side driving circuit. In case of the pixel section of a VGA display, for example, 480 gate wirings are provided and a total of 18 select lines of nine bits (n=9) are, therefore, necessary. Each select line 102 transmits a signal shown in the timing chart of FIG. 2. As shown in FIG. 2, if it is assumed that the frequency of A1 is 1, that of A2 is 2⁻¹, that of A3 is 22 and that of An is 2⁻⁽ⁿ⁻¹).

In addition, reference symbol 103a denotes a NAND circuit (or NAND cell) in the first stage, 103b denotes a NAND circuit in the second stage, and 103c denotes a NAND circuit in the n-the stage. Since NAND circuits as many as the gate wirings are required, n NAND circuits are required in case of FIG. 1. In other words, according to the present invention, the decoder 100 consists of a plurality of NAND circuits.

Further, each of the NAND circuits 103a to 103c is constituted out of a combination of p channel type TFT's 104 to 109. Actually, 2n TFT's are employed in each NAND circuit 103. In addition, the gate of each of the p channel type TFT's 104 to 109 is connected to one of the select lines 102 (A1, /A1, A2, /A2, . . . An and /An).

Here, in the NAND circuit 103a, the p channel type TFT's 104 to 106 each having a gate connected to one of the select lines A1, A2 . . . and An (to be referred to as “positive select lines” hereinafter) are connected in parallel. The sources of the p channel type TFT's 104 to 106 are connected to a positive power supply line (VDH) in common and the drains thereof are connected to an output line 111 in common. Further, the p channel type TFT's 107 to 109 each having a gate connected to one of select lines /A1, /A2, . . . /An (to be referred to as “negative select lines” hereinafter) are connected in series. The source of the p channel type TFT 109 located on one circuit end is connected to a negative power supply line (VDL) 112 and the drain of the p channel type TFT 107 located on the other circuit end is connected to an output line 111.

As can be seen, according to the present invention, each NAND circuit includes n TFT's (p channel type TFT's in this case) of one conductive type which are connected in series and n TFT's (p channel type TFT's in this case) of one conductive type which are connected in parallel. It is noted, however, that the n NAND circuits 103a to 103c differ in combinations of the p channel type TFT's and the select lines. That is, only one output line 111 is always selected and a signal is inputted into the select line 102 so that the output lines 111 are sequentially selected from one end to the other end.

Next, the buffer 101 is formed out of a plurality of buffers 113a to 113c corresponding to the NAND circuits 103a to 103c, respectively. The buffers 113a to 113c may have the same structure.

Further, each of the buffers 113a to 113c is constituted out of p channel type TFT's 114 to 116 (TFT's of one conductive type). The output line 111 from the decoder is inputted as the gate of the p channel type TFT 114 (TFT of the first conductive type). The p channel type TFT 114 has a ground power supply line (GND) 117 as a source and a gate wiring 118 as a drain. In addition, the p channel type TFT 115 (second TFT of the conductive type) has the ground power supply line 117 as a gate, a positive power supply line (VDH) 119 as a source and the gate wiring 118 as a drain. The p channel type TFT 115 is always turned on.

Namely, according to the present invention, each of the buffers 113a to 113c includes the first TFT of the conductive type (p channel type TFT 114) and the second TFT of the conductive type (p channel type TFT 115) which is connected in series to the first TFT of the conductive type (p channel type TFT 114) and which has the drain of the first TFT of the conductive type as a gate.

Further, a p channel type TFT 116 (third TFT of the conductive type) has a reset signal line (Reset) as a gate, the positive power supply line 119 as a source and the gate wiring 118 as a drain. It is noted that the ground power supply line 117 may be a negative power supply line (which should be, however, a power supply line which applies voltage for rendering the p channel type TFT used as the switching element of the pixel an on-state).

With this configuration, the channel width (assumed as W1) of the p channel type TFT 115 and the channel width (assumed as W2) of the p channel type TFT 114 satisfies a relationship of W1<W2. The channel width is the length of a channel formation region in the direction perpendicular to a channel length.

The buffer 113a operates as follows. If positive voltage is applied to the output line 111, the p channel type TFT 114 is turned off (in a state in which no channel is formed). On the other hand, the p channel type TFT 115 is always turned on (in a state in which a channel is formed), so that the voltage of the positive power supply line 119 is applied to the gate wiring 118.

On the other hand, if negative voltage is applied to the output line 111, the p channel type TFT 114 is turned on. At this time, since the channel width of the p channel type TFT 114 is larger than that of the p channel type TFT 115, the potential of the gate wiring 118 is attracted to the output of the p channel type TFT 114 and the voltage of the ground power supply line 117 is eventually applied to the gate wiring 118.

Accordingly, if the negative voltage is applied to the output line 111, the gate wiring 118 outputs negative voltage (which allows the p channel type TFT used as the switching element of the pixel to be turned on). If the positive voltage is applied to the output line 111, the gate wiring 118 always outputs positive voltage (which allows the p channel type TFT used as the switching element of the pixel to be turned off).

It is noted that the p channel type TFT 116 is used as a reset switch which forces the voltage of the gate wiring 118, to which the negative voltage is applied, to be raised to positive voltage. That is, when the select period of the gate wiring is finished. A reset signal is inputted and positive voltage is applied to the gate wiring 118. It is noted, however, that the p channel type TFT 116 can be omitted.

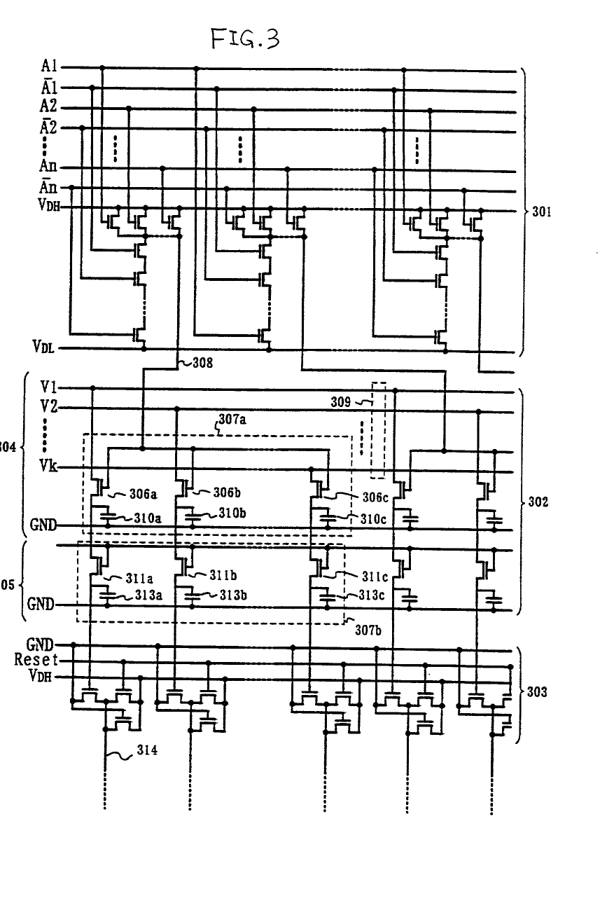

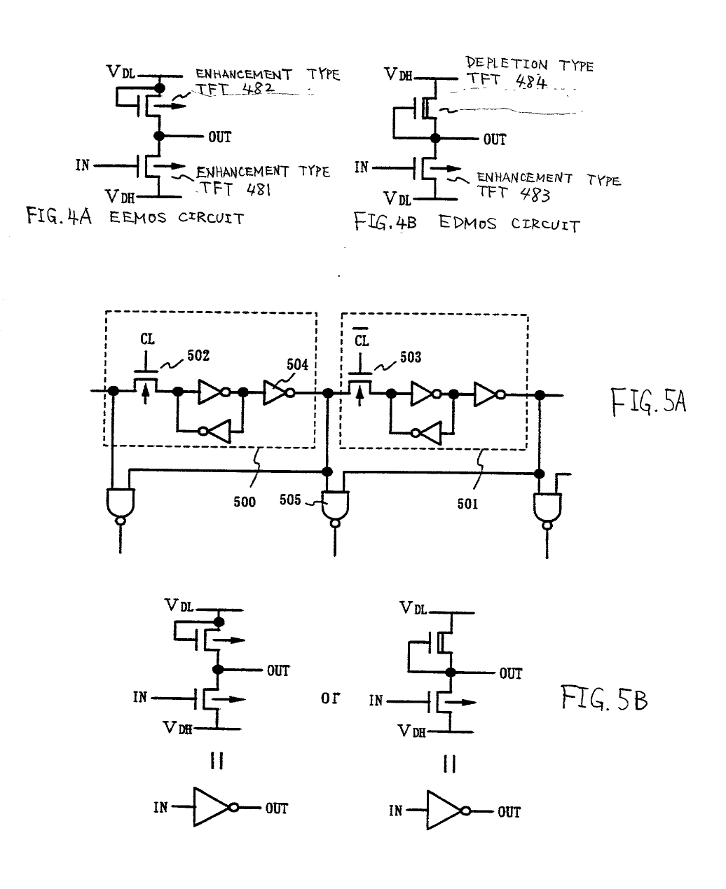

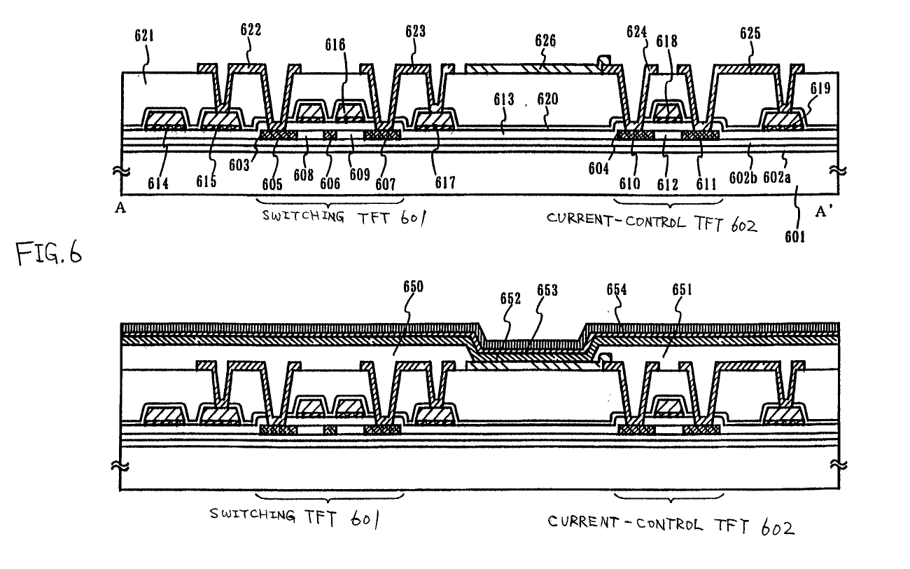

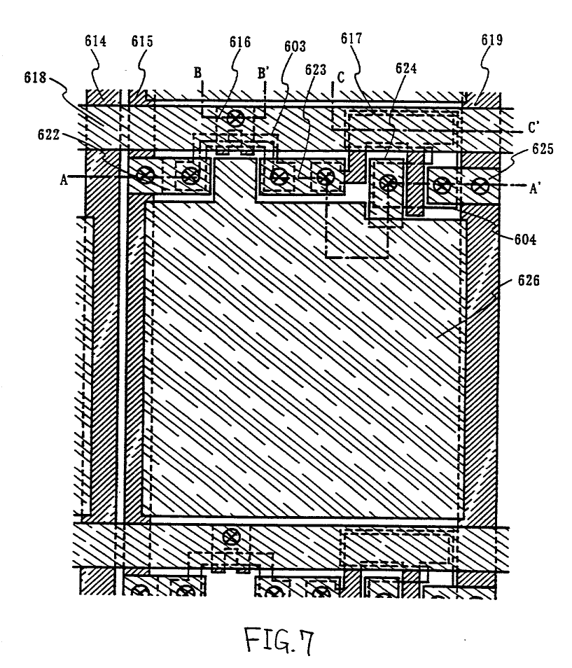

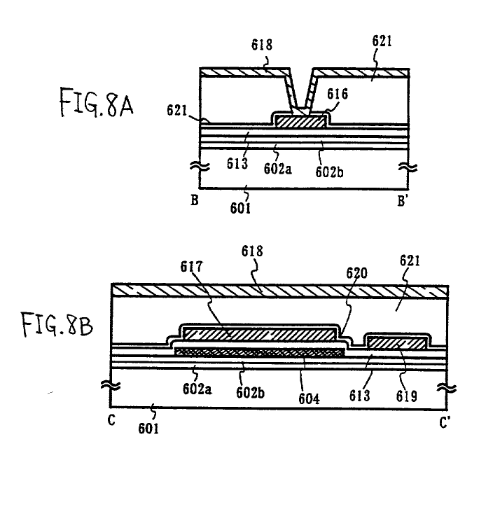

By the above-stated operation of the gate side driving circuit, the gate wirings are sequentially selected. The configuration of a source side driving circuit will be shown in FIG. 3. The source side driving circuit shown in FIG. 3 includes a decoder 301, a latch 302 and a buffer 303. Since the configurations of the decoder 301 and the buffer 303 are the same as those of the gate side driving circuit, they will not be described herein.

In case of the source side driving circuit shown in FIG. 3, the latch 302 consists of a latch 304 in the first stage and a latch 305 in the second stage. In addition, each of the latch 304 in the first stage and the latch 305 in the second stage includes a plurality of modular units 307 each of which consists of m p channel type TFT's 306a to 306c. An output line 308 from the decoder 301 is inputted into each of the gates of the m p channel type TFT's 306a to 306c which form each modular unit 307. It is noted that m is an arbitrary integer.

In case of the VGA display, for example, the number of source wirings is 640. If m is 1, 640 NAND circuits as many as the source wirings are necessary and 20 select lines (corresponding to 10 bits) are necessary. If m is 8, however, the number of NAND circuits is 80 and that of necessary select lines is 14 (corresponding to 7 bits). That is, if the number of source wirings is assumed as M, the number of necessary NAND circuit is (M/m).

The sources of the p channel type TFT's 306a to 306c are connected to video signal lines (V1, V2, . . . Vk) 309, respectively. That is, if negative voltage is applied to the output line 308, the p channel type TFT's 306a to 306c are simultaneously turned on and corresponding video signals are applied to the p channel type TFT's 306a to 306c, respectively. In addition, the video signals thus fetched are held by capacitors 310a to 310c connected to the p channel type TFT's 306a to 306c, respectively.

Further, the latch circuit 305 in the second stage also includes a plurality of modular units 307b and each modular unit 307b is constituted out of m p channel type TFT's 311a to 311c. The gates of the p channel type TFT's 311a to 311c are all connected to a latch signal line 312. If negative voltage is applied to the latch signal line 312, the p channel type TFT's 311a to 311c are simultaneously turned on.

As a result, the signals held in the capacitors 310a to 310c, respectively, are outputted to the buffer 303 simultaneously when the signals are held in capacitors 313a to 313c connected to the p channel type TFT's 311a to 311c, respectively. As described with reference to FIG. 1, the signals are outputted through the buffers to the source wirings 314. By the above-stated operation of the source side driving circuit, source wirings are sequentially selected.

As stated above, by forming the gate side driving circuit and the source side driving circuit only out of the p channel type TFT's, it is possible to form all of the pixel section and the driving circuits out of the p channel type TFT's. It is, therefore, possible to greatly improve the yield and throughput of TFT steps in the manuf acturing of the active matrix type display device and to thereby reduce manufacturing cost.

Even if one of the source side driving circuit and the gate side driving circuit is an external IC chip, the present invention can be carried out.

Furthermore, as PMOS circuits, there are known an EEMOS circuit formed out of enhancement type TFT's and an EDMOS circuit formed out of a combination of an enhancement type TFT and a depletion type TFT.

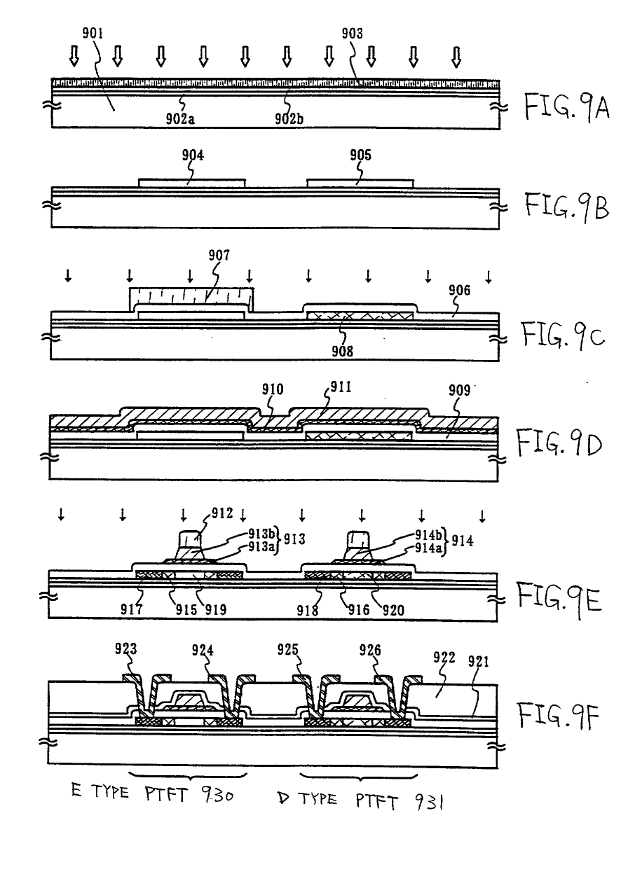

Here, one example of the EEMOS circuit and that of the EDMOS circuit are shown in FIGS. 4A and 4B, respectively. In FIG. 4A, each of reference symbols 401 and 402 denotes an enhancement type p channel type TFT (to be referred to as “E type PTFT” hereinafter). In FIG. 4B, reference symbol 403 denotes an E type PTFT and 404 denotes a depletion type p channel type TFT (to be referred to as “D type PTFT” hereinafter).

In FIGS. 4A and 4B, reference symbol VDH denotes a power supply line (positive power supply line) to which positive voltage is applied, VDL is a power supply line (negative power supply line) to which negative voltage is applied. The negative power supply line may be a power supply line at a ground potential (ground power supply line).

Furthermore, one example of manufacturing a shift register using the EEMOS circuit shown in FIG. 4A or the EDMOS circuit shown in FIG. 4B is shown in FIG. 5. In FIG. 5, reference symbols 500 and 501 denote flip-flop circuits, respectively. Reference symbols 502 and 503 are E type PTFT's, respectively. A clock signal (CL) is inputted into the gate of the E type PTFT 502 and a clock signal (/CL) reversed in polarity from the clock signal (CL) is inputted into the gate of the E type PTFT 503. Further, reference symbol 504 denotes an inverter circuit. As shown in FIG. 5B, the EEMOS circuit shown in FIG. 4A or the EDMOS circuit shown in FIG. 4B is used for the inverter circuit.

As stated above, if all the TFT's are p channel type TFT's, the number of steps of forming the n channel TFT's is reduced, making it possible to simplify the manufacturing steps of the active matrix type display device. Following this, the yield of the manufacturing steps is improved to make it possible to reduce the manufacturing cost of the active matrix type display device.

Embodiment 1

The present invention is characterized by forming a driving circuit out of only p channel type TFT's. Likewise, the pixel section is formed out of only p channel type TFT's. In this embodiment, therefore, one example of the structure of the pixel section which displays an image by a signal transmitted by the driving circuits shown in FIGS. 1 and 3 will be described.

The pixel structure of an active matrix type self-luminous display device according to the present invention is shown in FIGS. 6 and 7. FIG. 6 is a cross-sectional view of one pixel, and FIG. 7 is a top view of the pixel. It is noted that FIG. 6 represents a cross-sectional view taken along line A-A′ of FIG. 7 and the same elements are denoted by the same reference symbols in FIGS. 6 and 7.

In FIG. 6, reference symbol 601 denotes a substrate transparent to visible light, 602a and 602b denote basecoat layers, respectively. As the substrate transparent to visible light, a glass substrate, a quartz substrate, a crystallized glass substrate or a plastic substrate (including a plastic film) can be used. Each basecoat layer is formed out of a silicon oxide film, a silicon nitride film, a silicon oxide nitride film (represented by SiOₓN_{y}) or the like. The basecoat layer is formed to have a thickness of 50 to 200 nm. For example, the basecoat layers are assumed to form a two-layer structure in which the basecoat layer 602a is a silicon oxide nitride film which is formed out of SiH₄ and NH₃ to have a thickness of 50 nm and the basecoat layer 602b is a silicon oxide nitride which is formed out of SiH₄ and N₂O by a plasma CVD method or a two-layer structure in which a silicon nitride film and a silicon oxide film formed by using a TEOS (Tetraethyl Ortho Silicate) are stacked.

In the preferred embodiment of the present invention, each TFT is formed on an insulator. The insulator may be an insulating film (which is typically a silicon-containing insulating film) or a substrate made of an insulating material (which is typically a quartz substrate). Accordingly, “on an insulator” means “on an insulating film” or “on a substrate made of an insulating material”.

A switching TFT 651 and a current-control TFT 652 are formed out of p channel type TFT's, respectively, on this silicon-containing insulating film 602b.

The switching TFT 651 has semiconductor regions including regions each made of a p type semiconductor (to be referred to as “p type semiconductor regions” hereinafter) 605 to 607 and regions each made of an intrinsic semiconductor or substantially an intrinsic semiconductor (to be referred to as “channel formation regions” hereinafter) 608 and 609, which are formed in a semiconductor film 603. In addition, the current-control TFT 652 has semiconductor regions including p type semiconductor regions 610 and 611 and a channel formation region 612 which are formed in a semiconductor film 604.

The p type semiconductor region 605 or 607 becomes the source region or drain region of the switching TFT 651. In addition, the p type semiconductor region 611 becomes the source region of the current-control TFT 652 and the p type semiconductor region 610 becomes the drain region of the p type TFT 652.

The semiconductor films 603 and 604 are covered with a gate insulating film 613 and a gate electrode 617 which is connected to power supply lines 614 and 619, a source wiring 615, a gate electrode 616 and the p type semiconductor region 607, is formed on the gate insulating film 613. These elements are simultaneously formed by the same material. As the material of these wiring and electrodes, tantalum (Ta), tungsten (W), molybdenum (Mo), niobium (Nb), titanium (Ti) or one of nitrides of these metals may be used. Alternatively, an alloy consisting of a combination of these metals or one of the silicides of these metals may be used.

In FIG. 6, reference symbol 620 denotes a passivation film consisting of a silicon nitride oxide film or a silicon nitride film, and an interlayer insulating film 621 is provided on the passivation film 620. A silicon-containing insulating film or an organic resin film is used as the interlayer insulating film 620. As the organic resin film, a polyimide, polyamide, acrylic resin or BCB (benzocyclobutene) film may be used.

Contact holes are formed in the passivation film 620 and the interlayer insulating film 621, and a connection wiring which connects the source wiring 615 to the p type semiconductor region 605 on the semiconductor film 603, a gate wiring 618 which is connected to the gate electrode 616, a connection wiring 623 which connects the p type semiconductor region 607 to the gate electrode 617, a connection wiring 625 which is connected to the power supply line 619 and the p type semiconductor region 611, and a connection wiring 624 which connects a pixel electrode 626 to the p type semiconductor region 610 are formed. These wirings are formed out of a material which mainly consists of aluminum (Al).

As shown in the top view of FIG. 7, by providing such a structure, it is possible to cover the channel formation regions 608 and 609 in the semiconductor film 603 with the gate wiring 618 and to thereby shield the channel formation regions 608 and 609 from light. It is also preferable that the p type semiconductor regions 605 to 607 in the semiconductor film 603 are shielded from light. Further, since the end portions of the pixel electrode 626 can be formed by overlapping the source wiring 615 and the power supply line 619 therewith, it is possible to set the pixel electrode large and to thereby improve the aperture ratio. Besides, the source wiring 615 and the power supply line 619 can function as light shielding films.

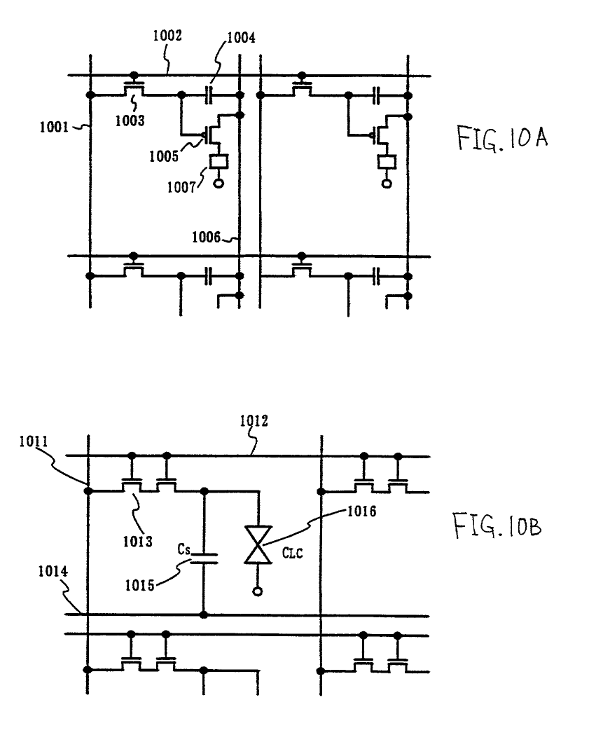

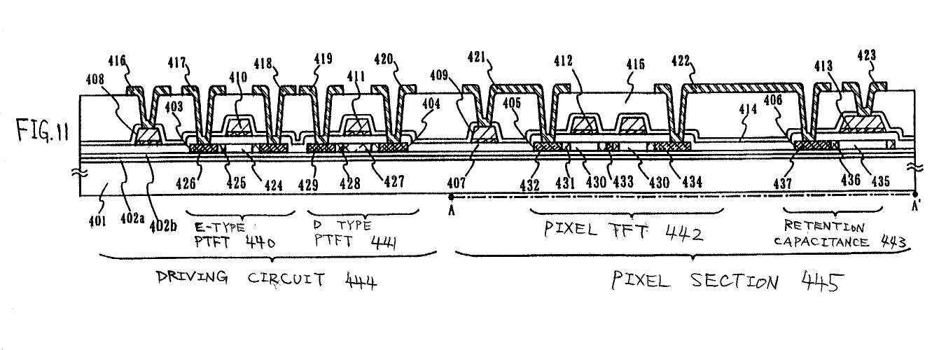

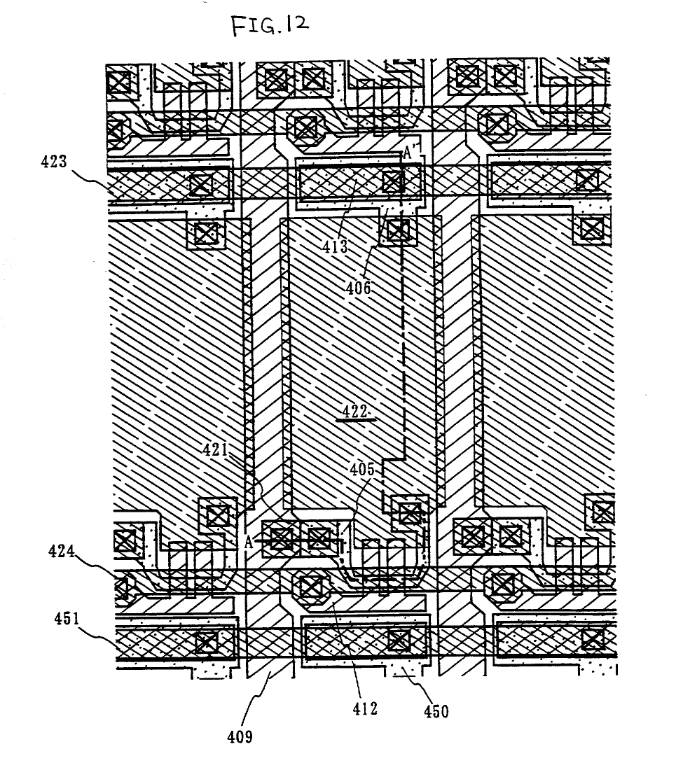

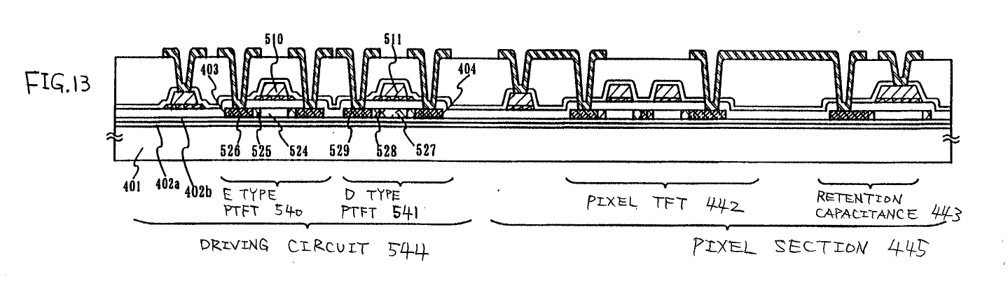

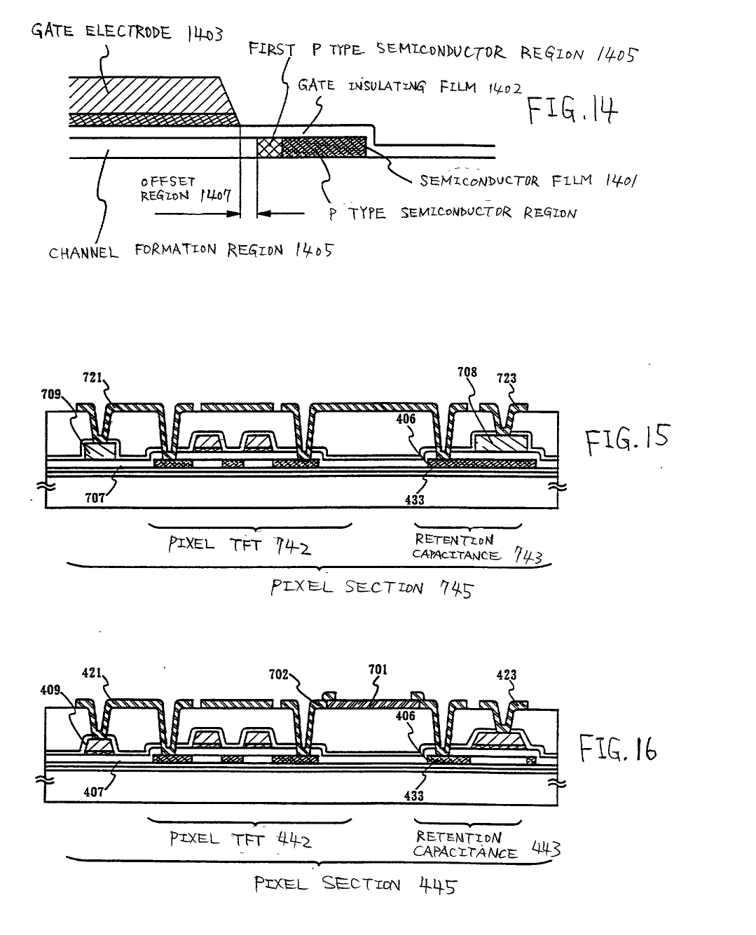

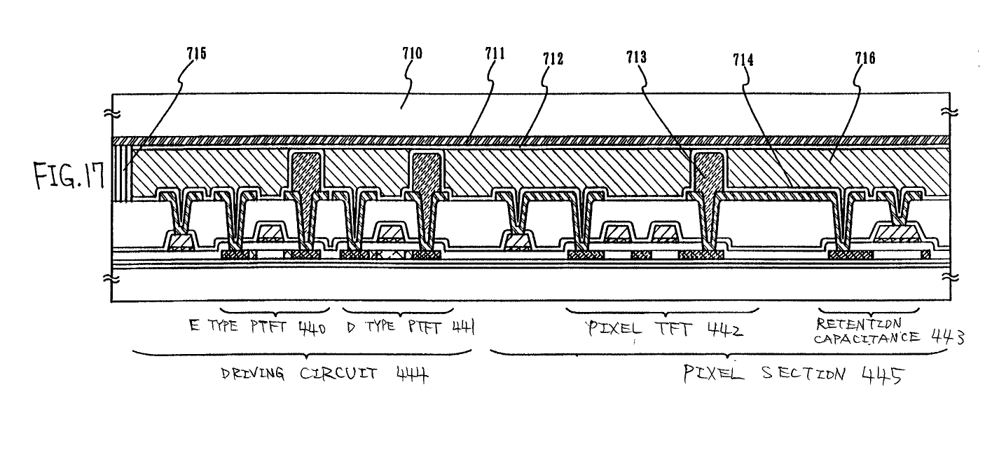

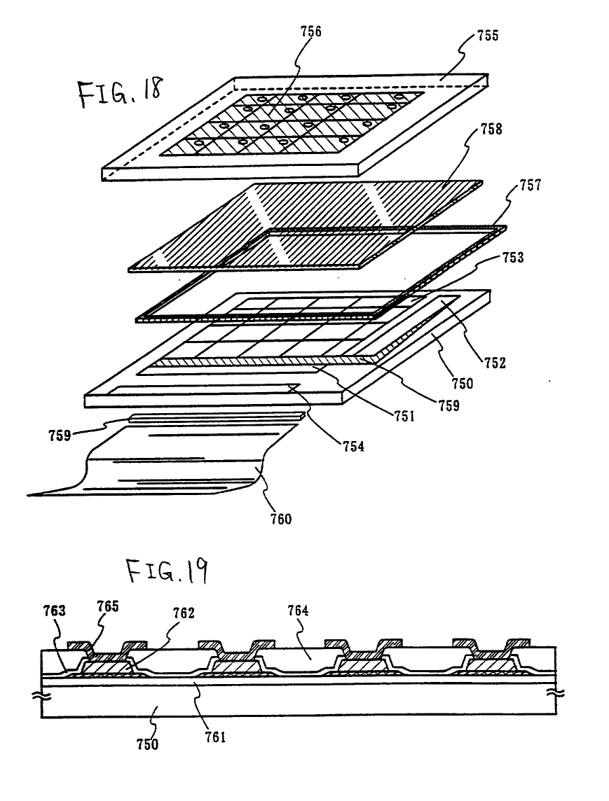

A cross-sectional view taken along line B-B′ of FIG. 7 is shown in FIG. 8A. FIG. 8A is a view for explaining a contact section between the gate wiring 618 and the gate electrode 616. The gate electrode 616 formed on the gate insulating film 613 is electrically connected to the gate wiring 618 in a region outside of the semiconductor film 603.

In addition, a cross-sectional view taken along line C-C′ of FIG. 7 is shown in FIG. 8B. FIG. 8B is a view for explaining the cross-sectional structure of a region which forms a capacitance. The capacitance is formed while using the semiconductor film 604 as one electrode, the gate insulating film 613 as a dielectric member and the gate electrode 617 as the other electrode.

An equivalent circuit diagram for such a pixel is shown in FIG. 10A. A TFT formed on the semiconductor film 603 functions as a switching TFT and a TFT formed on the semiconductor film 604 functions as a current-control TFT.

Next, as shown in FIG. 6B, insulators 650 and 651 made of resin are formed to conceal concave portion (recess resulting from the contact hole) and the end portions of the pixel electrode 626. They may be formed by forming an insulating film made of resin and then forming a predetermined pattern in accordance with the pixel electrode. At this moment, it is preferable that the height from the surface of the pixel electrode 626 to the top of the insulator 650 is not more than 300 nm (more preferably, not more than 200 nm). It is noted that these insulators 650 and 651 can be omitted.

The insulators 650 and 651 are formed to conceal the end portions of the pixel electrode 626 and to avoid the influence of the concentration of an electric field on the end portions. By doing so, it is possible to suppress the deterioration of an EL layer. In addition, the insulators 650 and 651 are formed to bury the concave portion of the pixel electrode which is formed because of the contact holes. By doing so, it is possible to prevent the coating error of the EL layer to be formed later and to prevent the pixel electrode from being short-circuited with a cathode to be formed later.

Next, the EL layer 652 having a thickness of 70 nm and a cathode 653 having a thickness of 300 nm are formed by a deposition method. In this embodiment, the structure of the EL layer 652 in which copper phthalocyanine(hole injection layer) having a thickness of 20 nm and Alq₃ (luminous layer) having a thickness of 50 nm are stacked is used. Needless to say, the other well-known structure in which a hole injection layer, a hole transport layer, an electron transport layer or electron injection is combined to a luminous layer may be used.

In this embodiment, phthalocyanine copper is first formed to cover all the pixel electrodes and then a red color luminous layer, a green color luminous layer and a blue color luminous layer are formed for the pixels corresponding to red, green and blue colors, respectively. The regions to be formed may be discriminated from one another by using shadow masks during deposition. By doing so, color display can be realized.

When the green color luminous layer is formed, Alq₃ (tris(8-quinolinolato)aluminum complex) is used as a host material of the luminous layer and quinacridon or coumarin 6 is added thereto as a dopant. When the red color luminous layer is formed, Alq₃ is used as a host material and DCJT, DCM1 or DCM2 is added thereto as a dopant. When the blue color luminous layer is formed, BAlq₃ (a penta-coordinated complex including a mixture ligand of 2-methyl-8-quinolinol and a phenol derivative) is used as a host material of the luminous layer and perylene is added thereto as a dopant.

Needless to say, it is not necessary to limit the material of the luminous layer to the above-stated organic material in the present invention. A well-known low molecular organic EL material, a high molecular organic EL material or an inorganic EL material can be used for the luminous layer. It is also possible to combine these materials. If the high molecular organic EL material is used, a coating method can be applied.

As stated above, the EL element which consists of a pixel electrode (anode) 836, an EL layer 839 and a cathode 840 is formed. Further, an auxiliary electrode 654 made of Al or the like may be formed on the cathode 653.

In this way, the active matrix type self-luminous device is completed. To form the EL layer and the cathode, a well-known technique is available. By providing the above-stated pixel structure, it is possible to greatly reduce the number of manufacturing steps for the active matrix type self-luminous device and to thereby manufacture an inexpensive active matrix type self-luminous device. It is also possible to provide an inexpensive electronic equipment which employs the active matrix type self-luminous device as a display section.

Embodiment 2

In this embodiment, steps of manufacturing an E-type PTFT and a D-type PTFT on the same insulator will be described with reference to FIG. 9.

First, as shown in FIG. 9A, a basecoat film (insulator) is formed on a glass substrate 901. In this embodiment, the first silicon nitride oxide film 902a having a thickness of 50 nm and the second silicon nitride oxide film 902b having a thickness of 200 nm are sequentially formed from the glass substrate 901 side to thereby form the basecoat film. In addition, the nitrogen content of the first silicon nitride oxide film 902a is set higher than that of the second silicon nitride oxide film 902b so as to suppress the diffusion of alkali metal from the glass substrate 901.

Next, an amorphous semiconductor film 903 having a thickness of 40 nm is formed on the basecoat film by the plasma CVD method. A material such as silicon or silicon germanium is used as the material of the amorphous semiconductor film. A laser beam is applied to the amorphous semiconductor film 903, thereby crystallizing the film 903 to form a polycrystalline semiconductor film (polysilicon film). It is not necessary to limit the crystallization method to a laser crystallization method but the other well-known crystallization method is available.

Next, as shown in FIG. 9B, using the first photomask, the polycrystalline semiconductor film is etched into a predetermined shape through a light exposure process, thereby forming individually isolated semiconductor films 904 and 905. It is noted that the semiconductor films denoted by reference symbols 904 and 905 form the channel formation region and the source and drain regions of a TFT when the TFT is completed.

To form a D-type PTFT, a step of doping the semiconductor films with an acceptor in advance is executed. First, a mask insulating film 906 consisting of a silicon oxide film is formed. This film is provided to control the concentration of the acceptor doped by using an ion doping method or an ion injection method. The concentration of the acceptor to be injected is set at 1×10¹⁶ to 1×10¹⁸/cm³. This doping is conducted to the channel formation region of the D-type PTFT. In FIG. 9C, the entire surface of the semiconductor film 905 is subjected to doping while the semiconductor film 904 which forms the E-type PTFT is coated with a mask 907 so that the semiconductor film 904 is not doped with the acceptor. This step is applied to the formation of the D-type PTFT.

In FIG. 9D, a gate insulating film 909 having a thickness of 80 nm is formed by the plasma CVD method. The gate insulating film 909 is formed out of silicon oxide, silicon oxide nitride film or the like. The first conductive film 910 formed out of tantalum nitride or titanium nitride is formed to have a thickness of 20 to 40 nm, preferably 30 nm. The second conductive film 911 is formed on the first conductive film 910. Ta, W, Mo, Nb, Ti or one of these metallic nitrides is used as the material of the second conductive film and the second conductive film is formed to have a thickness of 300 to 400 nm.

As shown in FIG. 9E, using the second photomask, a resist mask 912 is formed by a light exposure process and the conductive films are etched to thereby form gate electrodes 913 and 914, respectively. In this step by combined with the doping step, it is possible to form an LDD region and source and drain regions out of the p type semiconductor regions in the semiconductor films in a self-aligned manner. In the first etching processing to be performed first, an ICP (Inductively Coupled Plasma) etching method is used as a method suited for the first etching processing. The first etching processing is performed while mixing CF₄ and C1₂ into etching gas and supplying 500W RF (13.56 MHz) power to a coil type electrode at pressure of 0.5 to 2 Pa, preferably 1 Pa to thereby generate plasma. 100W RF (13.56 MHz) power (13.56 MHz) is supplied to the substrate side (sample stage) to apply thereto substantially negative self-bias voltage. If CF₄ and C1₂ are mixed into the etching gas, even the tungsten film, the tantalum nitride film or the titanium film can be etched at a similar rate.

On the above etching conditions, the end portions can be tapered by the shape of the mask made of a resist and the effect of the bias voltage applied to the substrate side. Each tapered portion is set to be at an angle of 15 to 45°. In addition, to perform etching without leaving any residue on the gate insulating film, it is desirable to lengthen etching time by about 10 to 20%. Since the select ratio of the silicon oxide nitride film to the W film is 2 to 4 (typically 3), the surface to which the silicon oxide nitride film is exposed is etched by about 20 to 50 nm by an over-etching processing.

Further, the second etching processing is performed. The ICP etching method is used, CF₄, Cl₂ and O₂ are mixed into etching gas, 500W RF power (13.56 MHz) is supplied to the coil-type electrode at pressure of 1 Pa to thereby generate plasma. 50 W RF (13.56 MHz) power is supplied to the substrate side (sample stage) and lower self-bias voltage than that used in the first etching processing is applied. On such conditions, the tungsten film is subjected to anisotropic etching to thereby leave the tantalum nitride film or titanium film which is the first conductive film. In this way, as shown in FIG. 9E, the gate electrodes 913 and 914 are formed out of the first conductive films 913a and 914a the end portions of which are located outside of the second conductive layers 913b and 914b, respectively.

Next, using the second conductive layers 913b and 914b as a mask, first p type semiconductor regions 915 and 916 are formed on the semiconductor films 904 and 905, respectively by the ion doping method. While applying acceleration voltage which can be passed through the first conductive layers 913a and 914a and the gate insulating film 909, acceptor of 1×10¹⁷ to 5×10¹⁹/cm³ is doped into the semiconductor films 904 and 905. As the acceptor, boron ions are typically used or an element which belongs to Group 13 of the periodic table may be added. In the ion doping method, B₂H₆, BF₃ or the like is used as source gas.

Furthermore, using the first conductive layers 913a and 914b and the second conductive layers 913b and 914b as a mask, the second p type semiconductor regions 917 and 918 are formed outside of the first p type semiconductor regions, respectively by the ion doping method. The second p type semiconductor regions become source and drain regions and acceptor of 1×10²⁰ to 1×10²¹/cm³ is doped into the second p type semiconductor regions.

In addition, channel formation regions 919 and 920 are formed in the regions in which the semiconductor films are overlapped with the second conductive layers 913b and 914b of the gate electrodes, respectively. Acceptor at lower concentration than that of the acceptor doped into the first p type semiconductor region 916 is added to the channel formation region 920.

Next, a heat treatment is performed to thereby activate the acceptor in the p type semiconductor regions. This activation may be carried out by furnace annealing, laser annealing, lamp annealing or a combination thereof. In this embodiment, the heat treatment is performed under a nitrogen atmosphere at 500° C. for four hours. During this time, it is preferable that oxygen in the nitrogen atmosphere is reduced as much as possible.

When the activation is finished, a silicon nitride oxide film having a thickness of 200 nm is formed as a passivation film 921 as shown in FIG. 9F and then the semiconductor layer is subjected to a hydrogenation treatment. A well-known hydrogen annealing technique or plasma hydrogenation technique may be used for the hydrogenation treatment. Further, an interlayer insulating film 922 made of resin and having a thickness of 800 nm is formed. Polyimide, polyamide, acrylic resin, epoxy resin or BCB (benzocyclobutene) may be used as the resin. Alternatively, an inorganic insulating film may be used as the interlayer insulating film.

Next, using the third photomask, contact holes are formed in the interlayer insulating film 922. Using the fourth photomask, wirings 923 to 926 are formed. In this embodiment, Ti—Al laminates are formed as the wirings 923 to 926, respectively. The contacts with the p type semiconductor regions are formed out of Ti so as to improve heat resistance.

In this way, an E-type PTFT 930 and a D-type PTFT 931 are completed. If only the E-type PTFT is formed, it can be completed using four photomasks. If the E-type PTFT and the D-type PTFT are formed on the same substrate, they can be completed using five photomasks.

In either case, an LDD overlapped with the gate electrode is formed to make it possible to prevent deterioration resulting from a hot-carrier effect or the like. Using such E-type PTFT's and D-type PTFT's, various circuits based on PMOS circuits can be formed. For example, as described in the embodiment, the EEMOS circuit and the EDMOS circuit described with reference to FIG. 4 can be formed.

Embodiment 3

One example of a reflection type display device using the E-type PTFT or D-type PTFT shown in the second embodiment is shown. One example of the pixel structure of the reflection type display device is shown in FIG. 12 and the cross-sectional structure thereof is shown in FIG. 11. A cross-sectional view taken along line A-A′ of FIG. 12 is shown in FIG. 11.

In FIG. 11, an E-type PTFT 440 and a D-type PTFT 441 in a driving circuit 444 are manufactured in the same steps as those in the second embodiment. The difference from the steps in the second embodiment is in that after a doping step of forming the second p type semiconductor region, the first conductive film is selectively etched to form the structure shown in FIG. 1. Etching is performed using mixture gas of Cl₂ and SF₆.

That is, a channel formation region 424, the first p type semiconductor region 425 (LDD region) which is not overlapped with a gate electrode 410 and second p type semiconductor regions 426 forming source and drain regions are formed in a semiconductor film 403. In addition, a channel formation region 427 which is doped with acceptor, the first p type semiconductor region 428 (LDD region) which is not overlapped with a gate electrode 411 and second p type semiconductor regions 429 forming source and drain regions are formed in a semiconductor film 404. Further, basecoat films 402a and 402b, semiconductor films 403 and 404, a gate electrode 407, gate electrodes 410 and 411, a passivation film 414, an interlayer insulating film 415, and wirings 417 to 420 are formed on a substrate 401. The wiring 408 under the interlayer insulating film 415 is formed on the same layer as that of the gate electrodes and the wiring 408 together with the wiring 416 form the wiring of the driving circuit.

On the other hand, a pixel TFT 442 in a pixel section 445 is formed out of an E-type PTFT and provided as a switching element which controls voltage applied to a pixel electrode. The pixel TFT 442 and a retention capacitance 443 are formed in the same steps as those of the TFT's of the driving circuit 444. In the pixel TFT 442, a channel formation region 430, the first p type semiconductor region 431 (LDD region) which is not overlapped with a gate electrode 412, second p type semiconductor regions 432 to 434 forming source and drain regions, the gate electrode 412, a source wiring 409, a connection wiring 421, a pixel electrode 422 and the like are formed on the semiconductor film 405. In this way, by providing the first p type semiconductor region 431 (LDD region) which is not overlapped with the gate electrode, OFF-state current is decreased.

In the step of selectively etching the first conductive film and thereby forming the first p type semiconductor region which is not overlapped with the gate electrode, an offset region can be formed by adjusting etching conditions. FIG. 14 is a view for explaining this state. Both the end portions of a gate electrode 1403 which consists of the first conductive film and the second conductive film are retreated, whereby an offset region 1407 to which no acceptor is added can be formed between one end portion of the gate electrode 1403 (or a channel formation region 1306) and one end portion of the first p type semiconductor region 1405. The offset region 1407 is adjustable in a range from about 10 to 1000 nm. The offset region enables the OFF-state current value of a PTFT to be reduced. It is particularly preferable to provide this region for the pixel TFT.

The retention capacitance 443 is formed out of a semiconductor film 406 which includes substantially an intrinsic semiconductor region 432 and a p type semiconductor region 433, a dielectric member formed on the same layer as that of the gate insulating film 407, a capacitance electrode 413 and a capacitance wiring 423.

FIG. 12 is a top view showing a pixel structure. In FIG. 12, the retention capacitance is formed out of an insulating film formed on the same layer as that of the gate insulating film on the semiconductor film 406 and serving as a dielectric member, the semiconductor film 406 and the capacitance electrode 413. The capacitance electrode 413 is connected to the capacitance wiring 423. The capacitance wiring is formed simultaneously with the pixel electrode 422, the connection electrode 421 and the gate wiring 424 on the same insulating film as that on which the pixel electrode 422, the connection electrode 421 and the gate wiring 424 are formed. The pixel electrode is formed so that the end portions thereof is overlapped with the source wiring 409. By providing such a structure, it is possible to set the pixel electrode large and to improve an aperture ratio. In addition, the source wiring 409 can function as a light shielding film. The arrangement of such a pixel electrode enables a reflection type liquid crystal display device, in particular, to have an improved aperture ratio.

Meanwhile, the magnitude of the retention capacitance provided in the pixel can be determined according to a liquid crystal material to be used and the OFF-state current value of the pixel TFT. The ratio of a retention capacitance Cₛ to a liquid crystal capacitance C_{LC} shown in the equivalent circuit of FIG. 10B is Cₛ/C_{LC}=2.7 to 4.5 if nematic liquid crystals are used, and Cₛ/C_{LC}=7.5 if antiferroelectric liquid crystals (AFLC) are used.

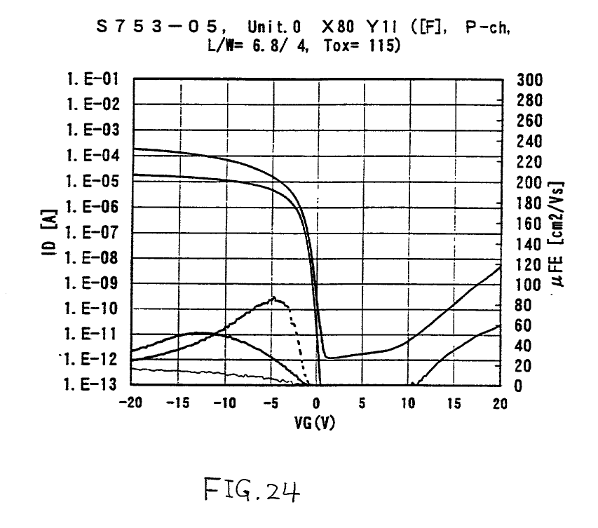

FIG. 24 shows the gate voltage (VG)-to-drain current (ID) characteristic of a PTFT of a single drain, multi-gate structure having a channel length of 6.8 μm and a channel width of 4 μm. If attention is paid to drain voltage (VD)=14V and gate voltage (VG)=4.5V, and an OFF-state current value (I_{off}) at that time is standardized based on the channel width, then 0.4 pA/μm of OFF-state current value can be obtained. This value is sufficiently practical.

Based on the above numerical values, the relationship between the OFF-state current value and the retention capacitance is defined by the following equation.

$$\frac{{I}_{off}}{{C}_{s} / {C}_{LC}} \qquad ( Equation 3 )$$

Therefore, if the nematic liquid crystals are used, the OFF-state current value is about 0.08 to 0.1 pA/μm. if AFLC's are used, the OFF-state current value is about 0.05 to 0.07 pA/μm.

Using the E-type PTFT 440 or D-type PTFT in the driving circuit 444 shown in FIG. 11, the driving circuit shown in FIGS. 1 and 3 can be formed. In addition, the equivalent circuit for the pixel section 445 is the same as that shown in FIG. 10B. In this way, one substrate (which is referred to as “element substrate” in the present specification) for forming an active matrix type liquid crystal display device can be formed.

Embodiment 4

One example of changing the LDD structure of a PTFT in a driving circuit in view of the deterioration of the PTFT on the element substrate shown in FIG. 11 will be described with reference to FIG. 13. On the element substrate shown in FIG. 13, the configurations of a pixel TFT 442 in a pixel section 445 and a retention capacitance 443 are the same as those in the third embodiment. They will not be, therefore, described herein.

In FIG. 13, an E-type PTFT 540 and a D-type PTFT 541 are formed in a driving circuit 544. These TFT's can be manufactured in the same steps as those show in FIG. 6 in the second embodiment. In the E-type PTFT 540, a channel formation region 524, a first p type semiconductor region 525 (LDD) which is overlapped with a gate electrode 510 and second p type semiconductor regions 526 forming source and drain regions are formed in a semiconductor film 503. In addition, a channel formation region 528 which is doped with acceptor, the first p type semiconductor region 528 (LDD) which is overlapped with a gate electrode 511 and second p type semiconductor regions 529 which form source and drain regions are formed in a semiconductor film 504 of the D-type PTFT 541.

To make the LDD structure different between the driving circuit 544 and the pixel section 455, a light exposure process is added after the doping step. A resist mask covering the driving circuit 544 is formed and the first conductive film of a pixel TFT 442 in the pixel section 455 is selectively etched, whereby the configuration shown in FIG. 13 can be realized. By providing the LDD region which is overlapped with the gate electrode in each TFT of the driving circuit 544, it is possible to prevent the deterioration of the TFT's resulting from the hot-carrier effect or the like. It can be suited to be used, in particular, for a buffer circuit, a level shifter circuit or the like.

Embodiment 5

If the active matrix type liquid crystal display device is considered to be used for a television receiver, the display device is required to make a screen size large and to improve accuracy. However, if the screen is large in size and the accuracy is improved, the number of scanning lines (gate wirings) increases and the length of each scanning line increases, thereby making it more necessary to decrease the resistances of the gate wirings and source wirings. That is, as the number of scanning lines increases, charge time for charging liquid crystals is shortened. It is, therefore, necessary to decrease the time constant (resistance×capacitance) of each gate wiring and to realize high speed response. If the specific resistance of a material for the gate wiring is, for example, 100 μΩcm, the limit of the screen size is almost 6-inch class. If the specific resistance thereof is 3 μΩcm, up to about 27-inch class size can be used.

A wiring material selected in light of the specific resistance is Al or Cu. FIG. 15 shows one example of manufacturing a source wiring out of Al or the like in the same configuration of a pixel section as that shown in FIG. 11 or 13. In a pixel section 745, a pixel TFT 442 is the same in configuration as that in the third or fourth embodiment. Source wirings 709 are formed on a gate insulating film 707 and each source wiring 709 in combination with a connection wiring 421 forms a contact. This source wiring 709 is formed out of a material mainly consisting of Al or Cu and the specific resistance thereof is set to be not more than 10 μΩcm, preferably not more than 3 μΩcm. Since such a material is inferior in heat resistance, it is preferable to form the source wiring 709 after an activation step.

Likewise, a capacitance electrode 710 in a retention capacitance 443 can be formed out of a material mainly consisting of Al or Cu. By forming the capacitance electrode 710 later, a semiconductor film 406 which serves as the other electrode of the retention capacitance 443 can be formed out of a p type semiconductor region 733.

Since a gate wiring is formed out of a material mainly consisting of Al, it is possible to decrease the resistance of the gate wiring as well as that of the source wiring. Accordingly, the pixel structure shown in FIG. 15 can solve the disadvantage of wiring delay and deal with the demand for making the screen large in size. By combining the configuration of this embodiment with the first, third, fourth and sixth embodiment, an active matrix type display device can be formed.

Embodiment 6

In the third or fourth embodiment, the pixel electrode may be formed out of a transparent conductive film to form a transmission type liquid crystal display device. FIG. 16 shows one example of the formation of the transmission type liquid crystal display device. A pixel electrode 701 is formed on an interlayer insulating film 415 using a transparent conductive film material selected from among indium tin oxide (ITO), zinc oxide (ZnO), gallium-added zinc oxide and the like. The contact of the pixel electrode 701 with the source or drain region of a pixel TFT may be formed by using the transparent electrode 701 or using a connection electrode 702 as shown in FIG. 16.

If the configuration of this embodiment stated above is combined with the third, fourth and fifth embodiment, an active matrix type display device can be formed.

Embodiment 7

In this embodiment, steps of manufacturing an active matrix type liquid crystal display device from an element substrate which is manufactured according to the configuration of one of the third to sixth embodiments will be described. FIG. 17 shows a state in which an element substrate is bonded to an opposite substrate 710 by a sealing material 715. On the element substrate, columnar spacers 713 are formed. In a pixel section, the spacer may be formed in accordance with a contact section on a pixel electrode. Although depending on a liquid crystal material to be used, each spacer is set to have a height of 3 to 10 μm. Since a concave section corresponding to each contact hole is formed in the contact section, it is possible to prevent liquid crystal orientation from being disordered by forming the spacers in accordance with the contact section. Thereafter, an orientation film 714 is formed and a rubbing treatment is performed. A transparent conductive film 711 and an orientation film 712 are formed on the opposite substrate 710. The element substrate is then bonded to the opposite substrate, liquid crystals are injected to thereby form a liquid crystal layer 716.

FIG. 18 typically shows a manner in which the element substrate is bonded to and assembled with the opposite substrate. On an element substrate 750, a pixel section 753, a scanning line side driving circuit 752, a signal line side driving circuit 751, an external input terminal 754, a wiring 759 which connects the external input terminal to the input section of each circuit and the like are formed. On an opposite substrate 755, an opposite electrode 756 corresponding to the region of the active matrix substrate 750 in which the pixel section and the driving circuits are formed, is formed. The element substrate 750 is bonded to the opposite substrate 755 through a sealing material 757, and liquid crystals are injected to thereby provide a liquid crystal layer 758 inside of the sealing material 757. Further, an FPC (Flexible Printed Circuit) 760 is bonded to the external input terminal 754 of the element substrate 750. A reinforcement plate 759 may be provided to intensify the bonding strength of the FPC 760.

FIG. 19 shows a cross-sectional view of the external input terminal 754 to which the FPC is bonded. A terminal 762 is formed on the basecoat film 761 of the substrate 750 using the same layer as a gate electrode formed out of the first conductive film and the second conductive film. A passivation film 763 and an interlayer insulating film 764 are formed on the terminal 762. An opening section is formed on the electrode 762 and an electrode 765 preferably made of a transparent conductive film material is formed in the opening section and integrated with the electrode 762 to thereby form a terminal. The terminal is formed to have a width of 100 to 1000 μm and a pitch of about 50 to 200 μm.

The active matrix type liquid crystal display device manufactured as stated above can be used as a display device for various types of electronic equipment.

Embodiment 8

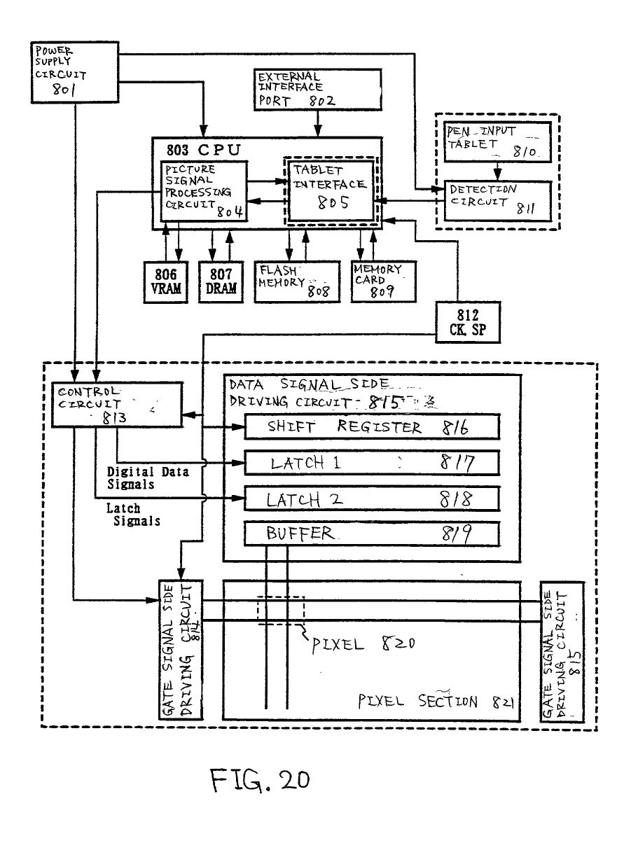

One example of an electronic equipment which employs the display device shown in the first to seventh embodiments will be described with reference to FIG. 20. In a display device shown in FIG. 20, a pixel section 821 which consists of pixels 820, a data signal side driving circuit 815 which is used to drive the pixel section, and gate signal side driving circuits 814 are formed out of TFT's on a substrate. While showing an example of digital driving, the data signal side driving circuit 815 consists of a shift register 816, latch circuits 817 and 818 and a buffer circuit 819. In addition, each gate signal side driving circuit 814 includes a shift register, buffers and the like (not shown).

A system block diagram of FIG. 20 shows the form of a portable information terminal such as a PDA. The pixel section, the gate signal side driving circuits 814 and the data signal side driving circuit 815 are formed on the display device.

The configurations of external circuits connected to this display device include a power supply circuit 801 which consists of a stabilization power supply and a high-speed, high-accuracy operational amplifier, an external interface port 802 provided with a USB terminal and the like, a CPU 803, a pen input tablet 810 used as input means, a detection circuit 811, a clock signal oscillator 812, a control circuit 813 and the like.

The CPU 803 includes a picture signal processing circuit 804, a tablet interface 805 which inputs a signal from the pen input tablet and the like. In addition, a VRAM 806, a DRAM 807, a flash memory 808 and a memory card 809 are connected to the CPU 803. Information processed by the CPU 803 is outputted, as a picture signal (data signal) from the picture signal processing circuit 804 to the control circuit 813. The control circuit 813 functions to convert a picture signal and a clock into those having the timing of the data signal side driving circuit 815 and that of the gate signal side driving circuit 814, respectively.

Specifically, the control circuit 813 has a function of allocating the picture signal to the data corresponding to respective pixels and a function of converting a horizontal synchronizing signal and a vertical synchronizing signal inputted from the outside into a start signal for the driving circuits and an alternating timing control signal for the power supply circuit included in the electronic equipment.

The portable information terminal such as a PDA is desired to be capable of using a chargeable battery as a power supply outdoors or in a train for a long period of time even if the terminal is not connected to an AC outlet. In addition, since portability is thought much of in the electronic equipment of this type, lightweight and small size are simultaneously demanded. If the capacity of a battery which occupies most of the weight of the electronic equipment increases, the weight of the electronic equipment increases. Accordingly, to decrease the consumption power of such an electronic equipment, it is necessary to take software-related measures such as the control of backlight lighting-up time and the setting of a stand-by mode.

For example, if an input signal from the pen input tablet 810 is not inputted into the tablet interface 805 of the CPU 803 for a certain period of time, the electronic equipment turns into a stand-by mode and the operations of the sections surrounded by a dotted line are synchronously stopped. Alternatively, measures such as including a memory in each pixel so as to switch a mode to a still image display mode are taken. By taking these measures, the consumption power of the electronic equipment is reduced.

If a still image is to displayed, the functions of the picture signal processing circuit 804 of the CPU 803, the VRAM 806 and the like are stopped, whereby it is possible to reduce the consumption power of the electronic equipment. In FIG. 20, the sections which operate are indicated by the dotted line. Further, the controller 813 may be attached to an element substrate by a COG method using an IC chip or formed integrally in the display device.

Embodiment 9

In the first to eighth embodiments, an organic resin material can be used for a substrate for forming PTFT's. As the organic resin material, polyethylene terephthalate, polyethylene naphthalate, polyether sulfone, polycarbonate, polyimide, aramid or the like can be used. Since the organic resin material has a lower specific gravity than that of a glass material, a display device which employs an organic resin substrate can contribute to making an electronic equipment lighter in weight. If a display device of, for example, a 5-inch class is considered to be mounted on an electronic equipment, the weight of the display device can be set at not more than log compared with about 60 g of the weight of a display device which employs a glass substrate.

However, since the organic resin material is inferior in heat resistance, a laser annealing method is positively utilized to form a polycrystalline silicon film and to activate acceptor. In the laser annealing method, excimer laser having a wavelength of 400 nm or less or the second harmonic (wavelength of 532 nm) to the fourth harmonic (wavelength 266 nm) of YAG or YVO₄ laser are used as a light source. The laser light is converged into a line or spot shape by an optical system and applied at an energy density of 100 to 700 mJ/cm² to be scanned over a predetermined region of the substrate to thereby perform annealing. By doing so, it is possible to perform the annealing without hardly heating the substrate.

Furthermore, since the organic resin material is inferior in abrasion resistance, it is preferable to coat the surface of the substrate with a DLC film. By coating the surface with the DLC film, the hardness of the surface increases, making it difficult to cause so-called scratches and making it possible to obtain a display screen which can be kept scratch-less, fine for a long period of time. As can be seen, by applying the organic resin substrate to the configurations in the first to eighth embodiments, an electronic equipment such as a portable information terminal can exhibit quite excellent advantage.

Embodiment 10

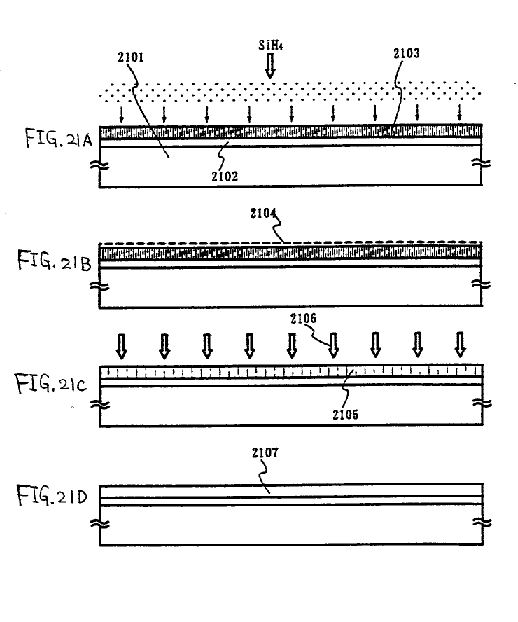

Another example of manufacturing a semiconductor film used to form PTFT's in the first to sixth embodiments will be described with reference to FIG. 21.

A semiconductor film manufacturing method described with reference to FIG. 21 is a crystallization method of adding elements to accelerate the crystallization of silicon to the entire surface of an amorphous silicon film. First, in FIG. 21A, a glass substrate represented by a #1773 glass substrate manufactured by Corning Inc. is used as a substrate 2101. A silicon oxide nitride film having a thickness of 100 nm is formed, as a basecoat film 2102, on the surface of the substrate 2101 with SiH₄ and N₂O by the plasma CVD method. The basecoat film 2102 is provided to prevent alkali metal contained in the glass substrate from being diffused into a semiconductor film formed on the upper layer of the basecoat film 2102.

An amorphous semiconductor film 2103 mainly consisting of silicon is manufactured by the plasma CVD method, SiH₄ is introduced into a reaction chamber and decomposed by intermittent discharge or pulse discharge to be thereby deposited on the amorphous semiconductor film 2101. The deposition conditions are that 27 MHz high frequency power is modulated, and intermittent discharge is conducted with a repeating frequency of 5 kHz and a duty ratio of 20% to thereby deposit it on the surface of the amorphous semiconductor film 2103 by a thickness of 54 nm. To decrease impurities such as oxygen, nitride and carbon contained in the amorphous semiconductor film 2103 mainly consisting of silicon as much as possible, SiH₄ with a purity of not less than 99.9999% is used. The specifications of a plasma CVD system are such that a composite molecular pump at a pumping speed of 300 L/second is provided in the first stage and a dry pump at a pumping speed of 400 m³/hr is provided in the second stage, whereby the vapor of the organic substance is prevented from being inversely diffused from the exhaust side, the degree of vacuum which the reaction chamber reaches is increased and impurity elements are prevented from being captured into the amorphous semiconductor film during the formation thereof as much as possible.

In this embodiment, one example of the plasma CVD method based on pulse discharge is shown. Needless to say, the amorphous semiconductor film may be formed by the plasma CVD method based on continuous discharge.

As shown in FIG. 7B, a nickel acetate salt solution containing nickel of 10 ppm converted into weight is coated on the amorphous semiconductor film 2103 by a spinner to thereby form a nickel-containing layer 2104. In this case, to make the solution more conformable to the film 2103, the amorphous semiconductor film 2103 mainly consisting of silicon is subjected to the following surface treatment. A very thin oxide film is formed with an ozone-containing aqueous solution, the oxide film is etched with a mixture solution of hydrofluoric acid and hydrogen peroxide water to form a clean surface and the resultant surface is then treated with an ozone-containing aqueous solution again to form a very thin oxide film. Since the silicon surface is inherently hydrophobic, it is possible to uniformly apply the nickel acetate salt solution by thus forming the oxide film.

Next, a heat treatment is performed at 500° C. for one hour to thereby emit hydrogen in the amorphous semiconductor film mainly consisting of silicon. A heat treatment is performed at 580° C. for four hours to thereby crystallize silicon. As a result, a crystalline semiconductor film 2105 shown in FIG. 21C is formed.

Further, a laser processing for applying a laser beam 2106 to the crystalline semiconductor film 2105 is performed so as to heighten the degree of crystallization (the rate of crystal components in the entire volume of the film) and to repair defects remaining in crystal grains. In the laser processing, excimer laser having a wavelength of 308 nm and oscillating with 30 Hz is used. The laser processing is performed while converging the laser beam at an energy density of 100 to 300 mJ/cm² by an optical system at an overlap rate of 90 to 95% without melting the semiconductor film. As a result, a crystalline semiconductor film 2107 mainly consisting of silicon shown in FIG. 21D can be obtained.

The crystalline semiconductor film 2107 thus manufactured is etched into a predetermined shape to form individually isolated semiconductor films. The semiconductor films manufactured by the method in this embodiment are excellent in crystallinity and capable of improving the field effect mobility and S value (sub-threshold factor) of a PTFT.

Embodiment 11

In the tenth embodiment, an amorphous semiconductor film consisting of silicon and germanium can be used. Such an amorphous semiconductor film can be manufactured by the plasma CVD method typically using SiH₄ and GeH₄ as material gas. If the amorphous semiconductor film consisting of silicon and germanium is used and the crystallization method described in the tenth embodiment is adopted, it is possible to obtain a crystalline semiconductor film having a {101} plane with an orientation rate of not less than 30%. In this case, the germanium content of the amorphous semiconductor film mainly consisting of silicon and germanium may be set at not more than 10 atomic %, preferably not more than 5 atomic %.

Embodiment 12

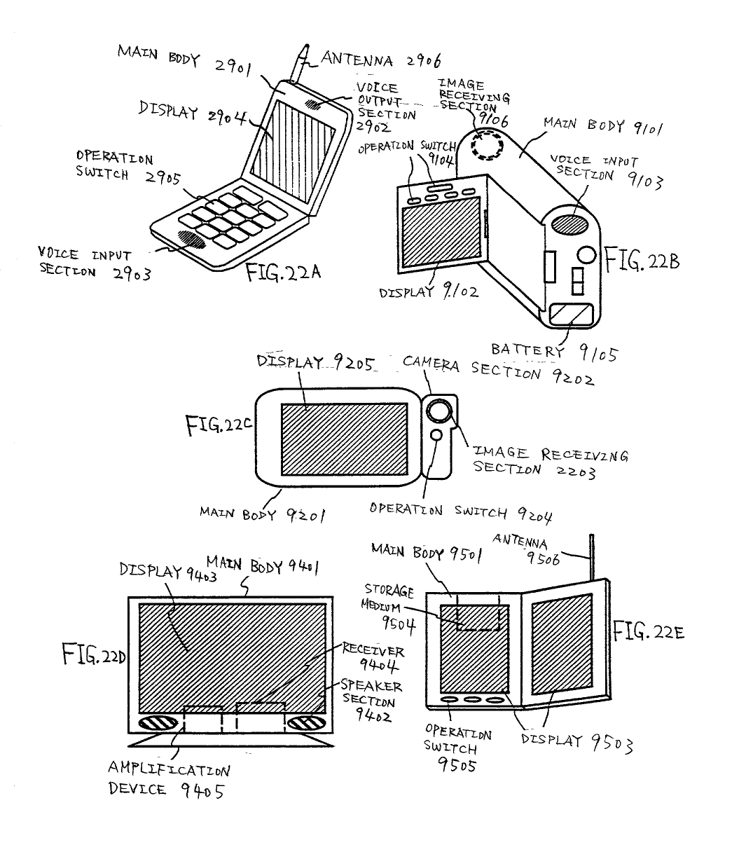

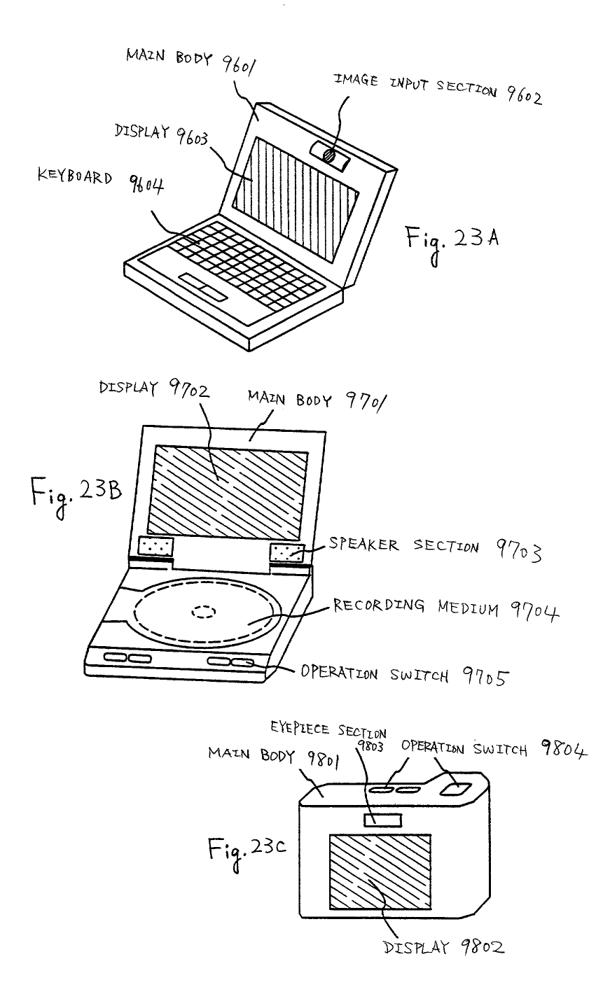

In this embodiment, an electronic equipment having the active matrix type display device of the present invention incorporated therein will be shown. The electronic equipment is exemplified by a portable information terminal (an electronic pocketbook, a mobile computer, a cellular phone or the like), a video camera, a still camera, a personal computer, a television and the like. The external terminal shown in the eighth embodiment may be connected to each of the electronic equipment mentioned herein. Their examples will be shown in FIGS. 22 and 23.

FIG. 22A shows a cellular phone which consists of a main body 2901, a voice output section 9002, a voice input section 2903, a display 2904, an operation switch 2905 and an antenna 2906. The present invention can be applied to the display 2904. The reflection type liquid crystal display device shown in the third or fourth embodiment is particularly suitable with a view of reducing consumption power.

FIG. 22B shows a video camera which consists of a main body 9101, a display 9102, a voice input section 9103, an operation switch 9104, a battery 9105 and an image receiving section 9106. The present invention can be applied to the display 9102. The reflection type liquid crystal display device shown in the third or fourth embodiment is particularly suitable with a view of reducing consumption power.

FIG. 22C shows a mobile computer or a portable information terminal which consists of a main body 9201, a camera section 9202, an image receiving section 9203, an operation switch 9204 and a display 9205. The present invention can be applied to the display 9205. The reflection type liquid crystal display device shown in the third or fourth embodiment is particularly suitable with a view of reducing consumption power.

FIG. 22D shows a television receiver which consists of a main body 9401, a speaker 9402, a display 9403, a receiving device 9404, an amplification device 9405 and the like. The present invention can be applied to the display 9403. The reflection type liquid crystal display device shown in the third or fourth embodiment is particularly suitable with a view of reducing consumption power.

FIG. 22E shows a portable book which consists of a main body 9501, displays 9502 and 9503, a storage medium 9504, an operation switch 9505 and an antenna 9506. The portable book displays data stored in a mini-disc (MD) or a DVD or data received through the antenna. The reflection type liquid crystal display device shown in the third or fourth embodiment is particularly suitable for the direct-view display 9502 or 9502 with a view of reducing consumption power.

FIG. 23A shows a personal computer which consists of a main body 9601, an image input section 9602, a display 9603 and a keyboard 9604. The present invention can be applied to the display 9603. The reflection type liquid crystal display device shown in the third or fourth embodiment is particularly suitable with a view of reducing consumption power.

FIG. 23B shows a player which employs a recording medium which records a program (to be referred to as “recording medium” hereinafter) which consists of a main body 9701, a display 9702, a speaker section 9703, a recording medium 9704 and an operation switch 9705. It is noted that this device employs a DVD (Digital Versatile Disc), a CD or the like as the recording medium and allows a user to enjoy music, movies, games and the Internet. The present invention can be applied to the display 9702. The reflection type liquid crystal display device shown in the third or fourth embodiment is particularly suitable with a view of reducing consumption power.

FIG. 23C shows a digital camera which consists of a main body 9801, a display 9802, an eyepiece section 9803, an operation switch 9804 and an image receiving section (not shown). The present invention can be applied to the display 9802. The reflection type liquid crystal display device shown in the third or fourth embodiment is particularly suitable with a view of reducing consumption power.

What is claimed is:

1. A display device having a pixel section and a driving circuit formed over a same insulator, wherein all TFT's for said pixel section and said driving circuit are p channel type TFT's; and each p channel type TFT of said pixel section has an offset gate structure.

2. A display device having a pixel section and a driving circuit formed over a same insulator, wherein all TFT's for said pixel section and said driving circuit are p channel type TFT's; each p channel TFT of said pixel section has an LDD region outside of a gate electrode thereof; and each p channel TFT of said driving circuit has an LDD region overlapped with a gate electrode thereof.

3. A display device having a pixel section and a driving circuit formed over a same insulator, wherein a switching TFT and a current-control TFT are provided in said pixel section; a TFT forming an inverter circuit is provided in said driving circuit; and said switching TFT, said current-control TFT and the TFT forming said inverter circuit are all p channel type TFT's.

4. A display device having a pixel section and a driving circuit formed over a same insulator, wherein all TFT's for said pixel section and said driving circuit are p channel type TFT's; and a source wiring and a gate electrode of said pixel section are formed over a first insulating film, and a gate wiring connected to the gate electrode crosses said source wiring through a second insulating film.

5. A display device having a pixel section and a driving circuit formed over a same insulator, wherein all TFT's for said pixel section and said driving circuit are p channel type TFT's; each p channel type TFT of said pixel section has an LDD region outside of a gate electrode thereof; each p channel type TFT of said driving circuit has an LDD region overlapped with a gate electrode thereof; a source wiring and the gate electrode of said pixel section are formed over a first insulating film, and a gate wiring connected to the gate electrode crosses said source wiring through a second insulating film.

6. A display device having a pixel section and a driving circuit formed over a same insulator, wherein a switching TFT and a current-control TFT are provided in said pixel section; a TFT forming an inverter circuit is provided in said driving circuit; said switching TFT, said current-control TFT and the TFT forming said inverter circuit are all p channel type TFT's; a source wiring and a gate electrode of said pixel section are formed over a first insulating film, and a gate wiring connected to the gate electrode crosses said source wiring through a second insulating film.

7. A display device having a pixel section and a driving circuit formed over a same insulator, wherein all TFT's for said pixel section and said driving circuit are p channel type TFT's; the p channel type TFT's, a retention capacitance and a liquid crystal layer are provided in said pixel section; each p channel type TFT of said pixel section has an LDD region outside of a gate electrode; said liquid crystal layer is formed out of nematic liquid crystals; and an OFF-state current value (Ioff) of each of said p channel type TFT's, said retention capacitance (Cs) and a capacitance (CLC) of said liquid crystal layer satisfy an equation:
$$\frac{{I}_{off}}{{C}_{s} / {C}_{LC}} ,$$
and the equation is not more than 0.1.

8. A display device having a pixel section and a driving circuit formed over a same insulator, wherein all TFT's for said pixel section and said driving circuit are p channel type TFT's; the p channel type TFT's, a retention capacitance and a liquid crystal layer are provided in said pixel section; each p channel type TFT of said pixel section has an LDD region outside of a gate electrode; said liquid crystal layer is formed out of antiferroelectric liquid crystals; and an OFF-state current value (I_{off}) of each of said p channel type TFT's, said retention capacitance (Cₛ) and a capacitance (C_{LC}) of said liquid crystal layer satisfy an equation:
$$\frac{{I}_{off}}{{C}_{s} / {C}_{LC}} ,$$
and the equation is not more than 0.06.

9. The display device according to any one of claims 1 to 8, wherein said driving circuit includes one of an EEMOS circuit and an EDMOS circuit.

10.The display device according to any one of claims 1 to 8, wherein said driving circuit includes a decode r cons isting of a plurality of NAND circuits.

11. A display device manufacturing method comprising:
a first step of forming a first semiconductor film for forming a TFT of a driving circuit over a n insulator, and a second semiconductor film for forming the TFT of a pixel section over the insulator;
a second step of forming a gate electrode consisting of a first conductive film and a second conductive film inside of the first conductive film, over each of an upper layer of said first semiconductor film and an upper layer of said second semiconductor film;
a third step of forming a first p type semiconductor region overlapped with said first conductive film, on each of said first semiconductor film and said second semiconductor film;
a fourth step of forming a second p type semiconductor region not overlapped with said first conductive film, in each of said first semiconductor film and said second semiconductor film; and
a fifth step of removing a section in which said first conductive film is overlapped with said first p type semiconductor region by etching.

12. A display device manufacturing method comprising:
a first step of forming a first semiconductor film for forming a TFT of a driving circuit over an insulator, and a second semiconductor film for forming the TFT of a pixel section over the insulator;
a second step of forming a gate electrode consisting of a first conductive film and a second conductive film inside of the first conductive film, over each of an upper layer of said first semiconductor film and an upper layer of said second semiconductor film;
a third step of forming a first p type semiconductor region overlapped with said first conductive film, in each of said first semiconductor film and said second semiconductor film;
a fourth step of forming a second p type semiconductor region not overlapped with said first conductive film, in each of said first semiconductor film and said second semiconductor film; and
a fifth step of removing a section in which said first conductive film over said second semiconductor film is overlapped with said first p type semiconductor region by etching.

13. A display device manufacturing method comprising:
a first step of forming a first semiconductor film for forming a TFT of a driving circuit over an insulator, and a second semiconductor film for forming a TFT of a pixel section over the insulator;
a second step of forming a gate electrode consisting of a first conductive film and a second conductive film inside of the first conductive film, over each of an upper layer of said first semiconductor film and an upper layer of said second semiconductor film;
a third step of forming a first p type semiconductor region overlapped with said first conductive film, over each of said first semiconductor film and said second semiconductor film;
a fourth step of forming a second p type semiconductor region not overlapped with said first conductive film, in each of said first semiconductor film and said second semiconductor film; and
a fifth step of removing a section in which said first conductive film over said second semiconductor film is overlapped with said first p type semiconductor region by etching, to form an offset region.

14. A display device manufacturing method comprising:
a first step of forming a first semiconductor film for forming a TFT of a driving circuit over an insulator, and a second semiconductor film for forming a TFT of a pixel section over the insulator;
a second step of forming a first insulating film over said first semiconductor film and said second semiconductor film;
a third step of forming a gate electrode consisting of a first conductive film and a second conductive film inside of the first conductive film, and a source wiring, over said first insulating film to correspond to each of said first semiconductor film and said second semiconductor film;
a fourth step of forming a first p type semiconductor region overlapped with said first conductive film, on each of said first semiconductor film and said second semiconductor film;
a fifth step of forming a second p type semiconductor region not overlapped with said first conductive film, in each of said first semiconductor film and said second semiconductor film;
a sixth step of removing a section in which said first conductive film is overlapped with said first p type semiconductor region by etching;
a seventh step of forming a second insulating film over said gate electrode and said source wiring; and
an eighth step of forming a gate wiring over said second insulating film.

15. A display device manufacturing method comprising:
a first step of forming a first semiconductor film for forming a TFT of a driving circuit over an insulator, and a second semiconductor film for forming a TFT of a pixel section over the insulator;
a second step of forming a first insulating film over said first semiconductor film and said second semiconductor film;
a third step of forming a gate electrode consisting of a first conductive film and a second conductive film inside of the first conductive film, and a source wiring, over said first insulating film to correspond to each of said first semiconductor film and said second semiconductor film;
a fourth step of forming a first p type semiconductor region overlapped with said first conductive film, in each of said first semiconductor film and said second semiconductor film;
a fifth step of forming a second p type semiconductor region not overlapped with said first conductive film, in each of said first semiconductor film and said second semiconductor film;
a sixth step of removing a section in which said first conductive film over said second semiconductor film is overlapped with said first p type semiconductor region by etching;
a seventh step of forming a second insulating film over said gate electrode and said source wiring; and
an eighth step of forming a gate wiring over said second insulating film.

16. A display device manufacturing method comprising:
a first step of forming a first semiconductor film for forming a TFT of a driving circuit over an insulator, and a second semiconductor film for forming the TFT of a pixel section over the insulator;
a second step of forming a first insulating film over said first semiconductor film and said second semiconductor film;
a third step of forming a gate electrode consisting of a first conductive film and a second conductive film inside of the first conductive film, and a source wiring, over said first insulating film to correspond to each of said first semiconductor film and said second semiconductor film;
a fourth step of forming a first p type semiconductor region overlapped with said first conductive film, in each of said first semiconductor film and said second semiconductor film;
a fifth step of forming a second p type semiconductor region not overlapped with said first conductive film, in each of said first semiconductor film and said second semiconductor film;
a sixth step of removing a section in which said first conductive film over said second semiconductor film is overlapped with said first p type semiconductor region by etching, to form an offset region;
a seventh step of forming a second insulating film over said gate electrode and said source wiring; and
an eighth step of forming a gate wiring over said second insulating film.
